(19) United States
(12) Patent Application Publication
(10) Pub. No.: US 2009/0296335 A1
(43) Pub. Date: Dec. 3, 2009

(54) Portable electronic device with holding frame

(75) Inventors: Chia-Shyong Cheng, Taipei (TW); Tsan-Ya Tai, Taipei (TW); Jung-Lung Lien, Taipei (TW)

Correspondence Address: BACON & THOMAS, PLLC, 625 SLATERS LANE, FOURTH FLOOR, ALEXANDRIA, VA, 22314-1176, US

(73) Assignee: FIRST INTERNATIONAL COMPUTER, INC., Taipei (TW)

(21) Appl. No.: 12/292,491

(22) Filed: Nov. 20, 2008

(30) Foreign Application Priority Data
Jun. 2, 2008 (TW) 097120447

(51) Int. Cl. H05K 7/16

(52) U.S. Cl. 361/679.27

(57) ABSTRACT

A portable electronic device comprises a main body and a holding frame. The main body comprises a monitor and a host, and the monitor is pivoted to the host. The holding frame is pivoted to the main body, and the holding frame is in a U shape. The holding frame comprises a pivot unit and a sliding unit. A first end portion of each pivot unit is pivoted to the main body, and the sliding unit is connected to the second end portion of the pivot unit. The sliding unit can slide out of a frame surrounding the monitor to form a holding portion.

### BACKGROUND OF THE INVENTION

1. Field of the Invention

The present invention relates to a portable electronic device; more particularly, the present invention relates to a portable electronic device with holding frame.

2. Description of the Related Art

Generally, the size of a laptop computer monitor is relatively small for the purpose of being carried conveniently. In the prior art, there is a laptop computer with a replaceable monitor, such that a user can replace the original monitor with a larger one. For example, if the user replaces the original 8.9 inch monitor with a 10.2 inch monitor, the monitor casing is larger than the host casing; as a result, the inharmonious state influences the appearance of the laptop computer.

Further, in the prior art, a laptop computer itself does not provide a component such as a handle or a strap for a user to hold. Therefore, when the user carries the laptop computer, he/she always needs to use a laptop bag. Because the bag itself has certain weight and volume, it causes additional burden to the user.

Therefore, there is a need to provide a portable electronic device with a holding frame to mitigate and/or obviate the aforementioned problems.

### SUMMARY OF THE INVENTION

It is an object of the present invention to provide a portable electronic device with a holding frame.

It is another object of the present invention to provide a portable electronic device for being carried conveniently.

It is yet another object of the present invention to provide a portable electronic device with a replaceable monitor capable of being replaced with a monitor of a different size, wherein the portable electronic device can further complement the size difference between the monitor and a host.

To achieve the aforementioned objects, the portable electronic device of the present invention comprises a main body and a holding frame. The main body comprises a monitor and a host, and the monitor is pivoted to the host. The holding frame is pivoted to the main body, and the holding frame is in a U shape. The holding frame comprises a pivot unit and a sliding unit. A first end portion of the pivot unit is pivoted to the main body, and the sliding unit is connected to a second end portion of the pivot unit. The sliding unit can slide out of a frame surrounding the monitor to form a holding portion.

According to one preferred embodiment of the present invention, the outline of the holding frame is substantially equal to the outline of the monitor. The holding frame has a first position and a second position. In the first position, the holding frame is located within the perimeter of the host; while in the second position, the holding frame is located within the perimeter of the monitor. When the holding frame is in the first position, the outline of the holding frame is larger than the outline of the host; when the holding frame is in the second position, the outline of the holding frame is substantially equal to the outline of the monitor.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 is an exploded view of a portable electronic device of the present invention.

FIG. 1A is an exploded view of a pivot unit and a sliding unit of a holding frame of the present invention.

FIG. 2 is an illustration of the portable electronic device of the present invention.

FIG. 3 is an illustration of the portable electronic device under a first usage state of the present invention.

FIG. 4 is an illustration of the portable electronic device under a second usage state of the present invention.

FIG. 5 is an illustration of the portable electronic device of the present invention from another viewing angle.

FIG. 6 illustrates the sliding unit sliding out of the frame of the present invention surrounding the monitor.

FIG. 7 illustrates a strap hole of the holding frame connected to a strap of the present invention.

### DETAILED DESCRIPTION OF THE PREFERRED EMBODIMENT

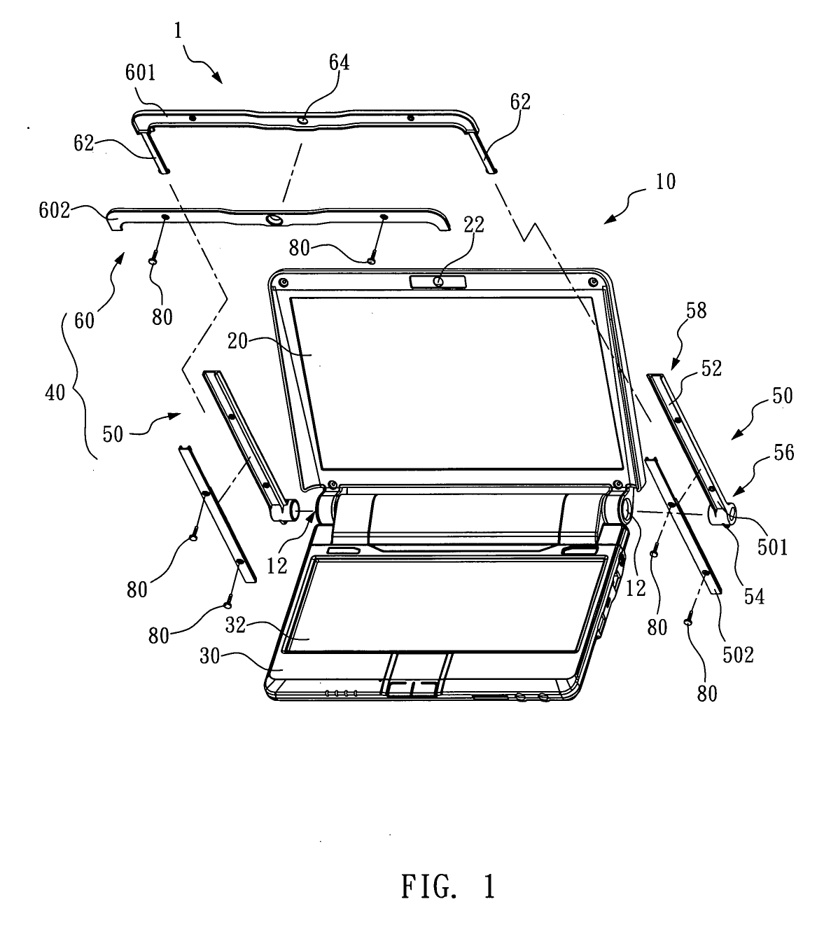

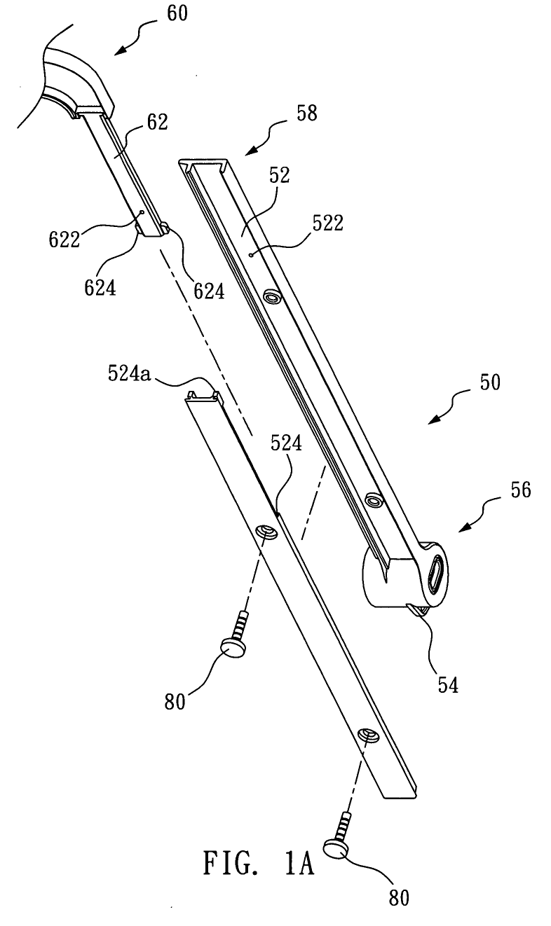

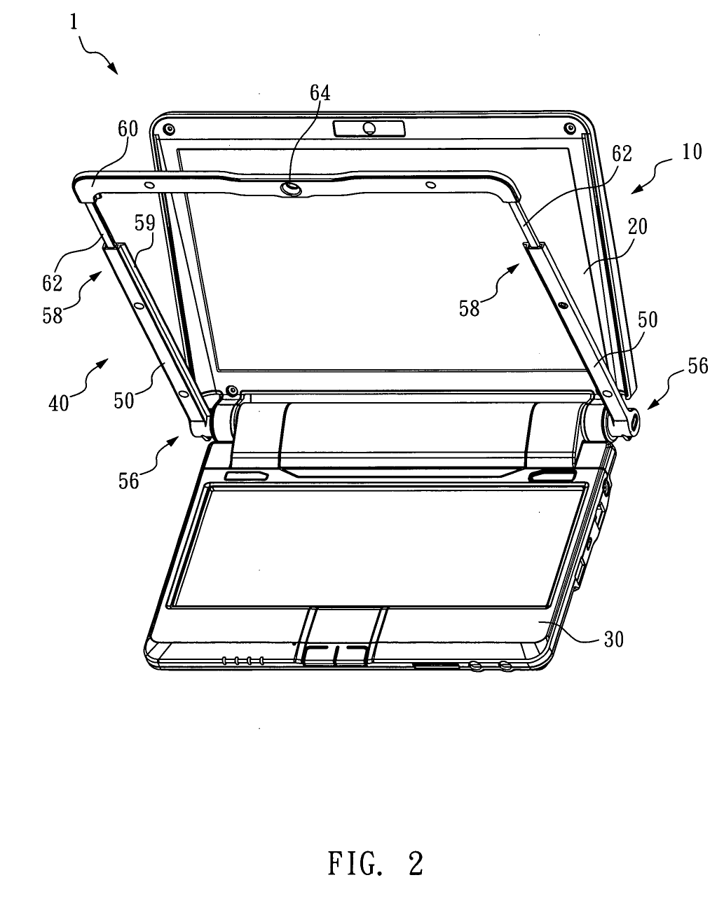

Please refer to FIG. 1, FIG. 1A and FIG. 2. FIG. 1 is an exploded view of a portable electronic device of the present invention. FIG. 1A is an exploded view of a pivot unit and a sliding unit of a holding frame of the present invention. FIG. 2 is an illustration of the portable electronic device of the present invention.

The portable electronic device 1 comprises a main body 10 and a holding frame 40. The holding frame 40 is pivoted to the main body 10. In this embodiment, the portable electronic device 1 is a laptop computer. However, the portable electronic device 1 is not limited to a laptop computer.

The main body 10 is a main structure of a general laptop computer, wherein the main body 10 comprises a monitor 20 and a host 30. The host 30 comprises a keyboard 32 for a user to input information. The monitor 20 is pivoted to the host 30, such that the monitor 20 and the host 30 can be folded together for the purpose of being conveniently carried or stored.

In this embodiment, the laptop computer is equipped with an 8.9 inch monitor. When the user replaces it with a larger monitor 20 (such as a 10.2 inch monitor), the surface area of the monitor 20 is larger than the surface area of the host 30. This situation results in an inharmonious state wherein the monitor 20 and the host 30 are different sizes. In the present invention, the size difference between an original-sized host 30 and a different-sized monitor 20 can be complemented.

The holding frame 40 is slightly in a U shape. The outline of the holding frame 40 is substantially equal to the outline of the monitor 20. The holding frame 40 comprises two pivot units 50 and a sliding unit 60. In this embodiment, there are two pivot units 50, which are located at two ends of the holding frame 40.

The pivot unit 50 comprises a first end portion 56 and a second end portion 58. The first end portion 56 of the pivot unit 50 is pivoted to a pivot shaft 12 of the main body 10. The second end portion 58 of the pivot unit 50 is connected to the sliding unit 60. In this embodiment, there are two pivot points, and the first end portion 56 of the pivot unit 50 is pivoted to the pivot shaft 12 of the main body 10, such that the monitor 20, the host 30, and the holding frame 40 are pivoted to the same pivot shaft 12. Further, the pivot unit 50 is an assembly of two components 501 and 502, and these two components 501 and 502 are combined into one by means of bolting units 80. The sliding unit 60 is also an assembly of two components 601 and 602, and these two components 601 and 602 are combined into one by means of bolting units 80. Please note that the sliding unit 60 can also be an in-mold member.

Another embodiment of the present invention is opposite to the aforementioned one. The surface area of the monitor 20 of the portable electronic device 1 can also be smaller than the surface area of the host 30. This situation results in an appearance of a small monitor 20 and a large host 30. At this time, the outline of the holding frame 40 is substantially equal to the outline of the host 30.

Further, the location, quantity and pivot method of and by which the holding frame 40 is pivoted to the main body 10 are not limited to the aforementioned embodiment. For example, the pivot unit 50 can be pivoted to the main body 10 by means of applying matching convex-concave structures, using a pivot shaft, or using a hinge, so as to achieve the object of relative rotation between the pivot unit 50 and the main body 10. Please note these techniques are known to a person skilled in the art.

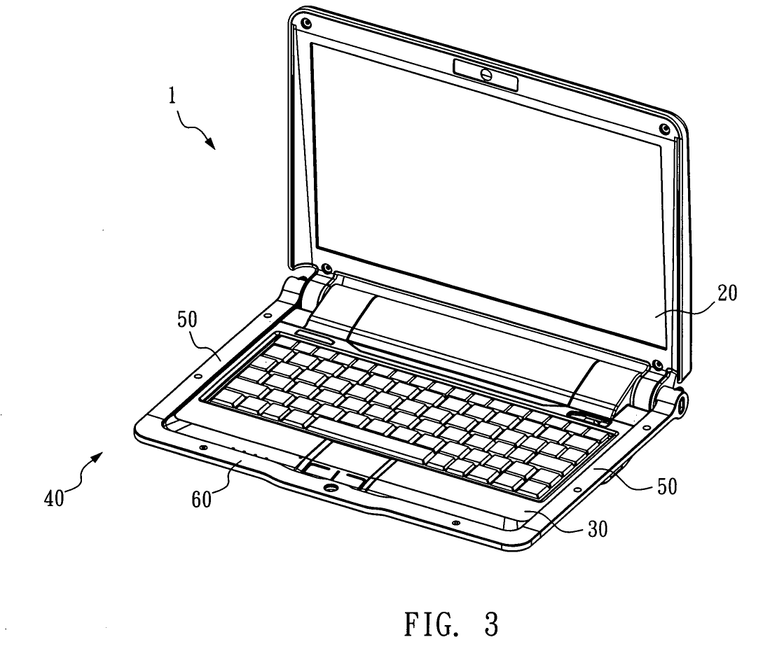

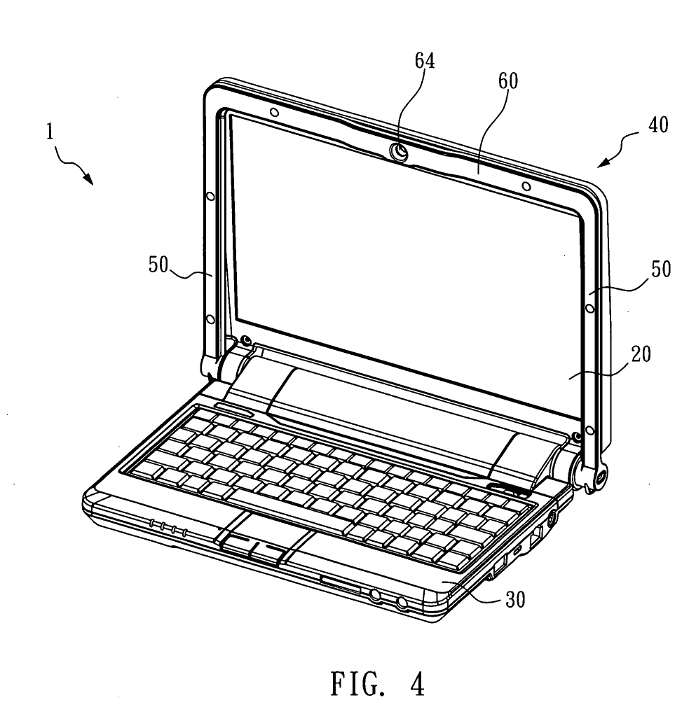

The holding frame 40 has a first position and a second position. Please refer to FIG. 3 and FIG. 4. FIG. 3 is an illustration of the portable electronic device under a first usage state of the present invention. FIG. 4 is an illustration of the portable electronic device under a second usage state of the present invention.

When the holding frame 40 is in the first position (as shown in FIG. 3), the holding frame 40 is located in the perimeter of the host 30. More precisely, when the holding frame 40 is in the first position, the outline of the holding frame 40 is larger than the outline of the host 30. At this time, the perimeter of the host 30 is surrounded by the holding frame 40, such that the surface area of the host 30 plus the surface area of the holding frame 40 is approximately equal to the surface area of the monitor 20, and therefore the upper half portion and the lower half portion of the portable electronic device 1 look harmonious as a whole.

When the holding frame 40 is in the second position (as shown in FIG. 4), the holding frame 40 is located in the perimeter of the monitor 20. More precisely, when the holding frame 40 is in the second position, the outline of the holding frame 40 is substantially equal to the outline of the monitor 20. At this time, the holding frame 40 covers the periphery of the monitor 20, such that the surface area where the holding frame 40 is superimposed on the monitor 20 is obviously larger than the surface area of the host 30.

Further, because there is a lens 22 installed in the upper edge of the monitor 20 of the portable electronic device 1, the sliding unit 60 has an opening 64 so as to prevent the holding frame 40 from obstructing the lens 22. When the holding frame 40 is in the second position, the opening 64 is located in a position corresponding to the lens 22, such that the lens 22 can successfully capture image frames.

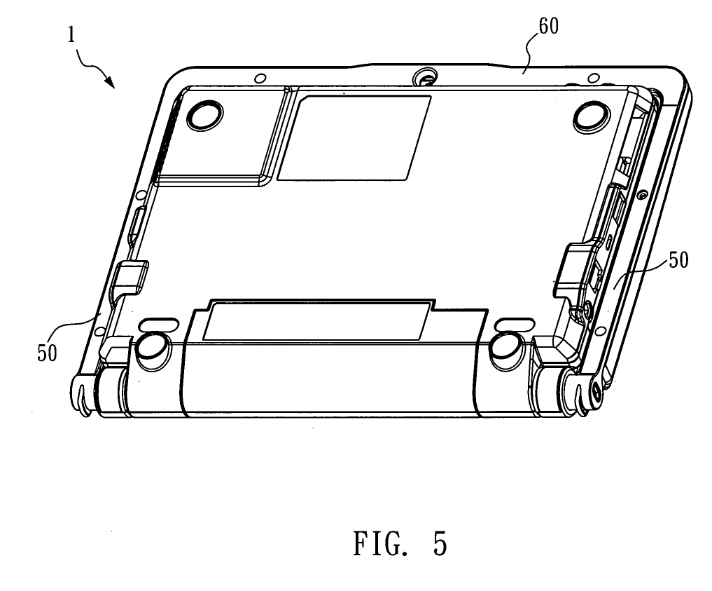

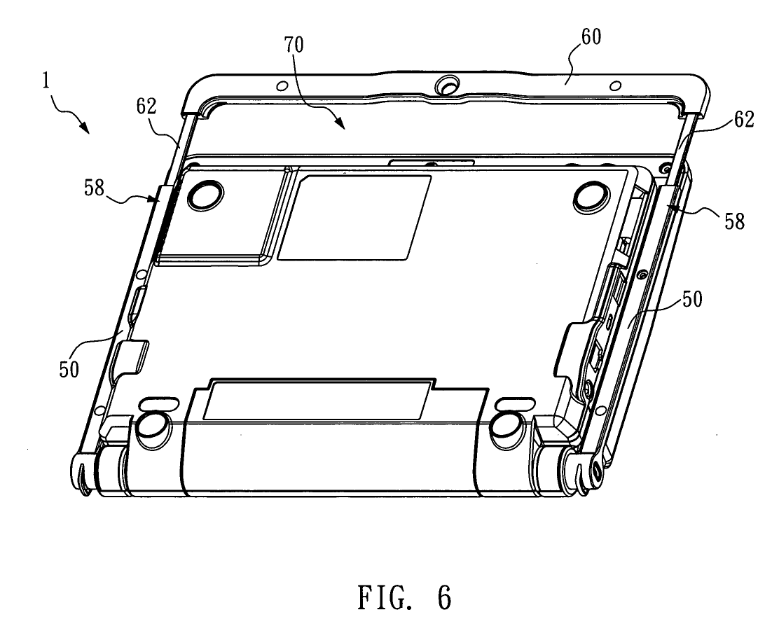

Please refers to FIG. 1, FIG. 1A, FIG. 5 and FIG. 6. FIG. 5 is an illustration of the portable electronic device of the present invention from another viewing angle. FIG. 6 illustrates the sliding unit sliding out of the frame of the present invention surrounding the monitor.

In this embodiment, the sliding unit 60 is connected to the second end portion 58 of the pivot unit 50. When the sliding unit 60 slides out of a frame surrounding the monitor 20, a holding portion 70 is accordingly formed (as shown in FIG. 6) for the user to hold.

There is another implementation of the present invention. That is, the size of the monitor 20 and the size of the host 30 of the portable electronic device 1 are matched with each other (i.e. both have substantially the same outline). At this time, the holding frame 40 is simply used as a handle. Please note this technique is known to a person skilled in the art.

As shown in FIG. 1A. In this embodiment, the pivot unit 50 comprises a sliding slot 52, the sliding unit 60 comprises a sliding shaft 62, and the sliding shaft 62 can slide within the sliding slot 52, such that the holding frame 40 has a retractable function. Please note that the retractable structure of the holding frame 40 is not limited to the above description. For example, the pivot unit can also comprise a sliding shaft, and the sliding unit can also comprise a sliding slot, thereby achieving a relative sliding mechanism as well.

In order to prevent the sliding shaft 62 from freely sliding within the sliding slot 52, in this embodiment, the sliding slot 52 further comprises a first positioning portion 522, and the sliding shaft 62 further comprises a second positioning portion 622, such that the first positioning portion 522 can be positioned to the second positioning portion 622. For example, the first positioning portion 522 is a convex point, and the second positioning portion 622 is a concave point. Please note that the structures of the first positioning portion 522 and the second positioning portion 622 are not limited to the above description. For example, the sliding slot and the sliding shaft can also be in a tight fit relation, such that the sliding shaft can be positioned at any position in the sliding slot within the sliding range.

In order to limit the sliding range of the sliding unit 60, in this embodiment, the sliding slot 52 further comprises first blocking portions 524 and 524a, and the sliding shaft 62 further comprises a second blocking portion 624. The first blocking position 524 can keep the second blocking portion 624 from moving inwards, and the first blocking portion 524a can keep the second blocking portion 624 from moving outwards.

Further, the pivot unit 50 has a protruding portion 59 (as shown in FIG. 2). The shape of the protruding portion 59 corresponds to the frame surrounding the host 30. When the monitor 20 and the host 30 are folded together in a folded state (as shown in FIG. 6), the protruding portion 59 is wedged in the frame surrounding of the monitor 20, such that the protruding portion 59 of the pivot unit 50 is placed between the monitor 20 and the host 30, thereby achieving a blocking and positioning function of the holding frame 40 in the folded state.

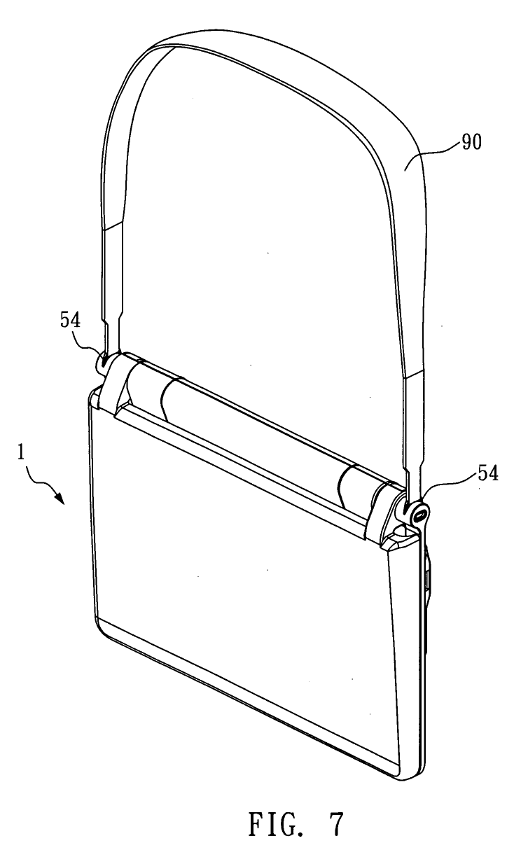

Please refer to both FIG. 1A and FIG. 7. FIG. 7 illustrates a strap hole of the holding frame connected to a strap of the present invention. In order to provide an easy-to-carry design for the user, the holding frame 40 further comprises a strap hole 54. In this embodiment, the strap hole 54 is located in the first end portion 56 of the pivot unit 50. The user needs only to put a strap 90 through the strap hole 54 so as to form a bag style.

Although the present invention has been explained in relation to its preferred embodiments, it is to be understood that many other possible modifications and variations can be made without departing from the spirit and scope of the invention as hereinafter claimed.

What is claimed is:

1. A portable electronic device, comprising:
a main body, comprising a monitor and a host, the monitor pivoted to the host; and
a holding frame, pivoted to the main body, and the holding frame is substantially in a U shape, the holding frame comprising:
two pivot units, located at two ends of the holding frame, each pivot unit having a first end portion and a second end portion, wherein the first end portion is pivoted to the main body; and
a sliding unit, connected to the second end portion of each pivot unit, wherein the sliding unit can slide out of a frame surrounding the monitor to form a holding portion.

2. The portable electronic device as claimed in claim 1, wherein the outline of the holding frame is substantially equal to the outline of the monitor or the outline of the host.

3. The portable electronic device as claimed in claim 1, wherein the holding frame has a first position and a second position; in the first position, the holding frame is located in the perimeter of the host, while in the second position, the holding frame is located in the perimeter of the monitor.

4. The portable electronic device as claimed in claim 3, wherein when the holding frame is in the first position, the outline of the holding frame is larger than the outline of the host; when the holding frame is in the second position, the outline of the holding frame is substantially equal to the outline of the monitor.

5. The portable electronic device as claimed in claim 1, wherein the holding frame further comprises at least one strap hole.

6. The portable electronic device as claimed in claim 5, wherein each strap hole is located in the first end portion of each pivot unit.

7. The portable electronic device as claimed in claim 3, wherein the monitor comprises a lens, and the sliding unit further comprises an opening; when the holding frame is in the second position, the opening is located in a position corresponding to the lens.

8. The portable electronic device as claimed in claim 3, wherein the main body comprises a pivot shaft, wherein the monitor, the host and the holding frame are all pivoted to the pivot shaft.

9. The portable electronic device as claimed in claim 1, wherein each pivot unit comprises a sliding slot, the sliding unit comprises at least one sliding shaft, and the sliding shaft can slide within the sliding slot.

10. The portable electronic device as claimed in claim 9, wherein the sliding slot further comprises a first positioning portion, the sliding shaft further comprises a second positioning portion, and the first positioning portion can be positioned to the second positioning portion.

11. The portable electronic device as claimed in claim 9, wherein the sliding slot further comprises a first blocking portion, the sliding shaft further comprises a second blocking portion, and the sliding range of the sliding unit is limited by using the first blocking portion to block against the second blocking portion.
